(19) United States
(12) Patent Application Publication
(10) Pub. No.: US 2026/0146198 A1
(43) Pub. Date: May 28, 2026

(54) QUANTUM DOTS AND ELECTROLUMINESCENT DEVICES

(71) Applicant: Yungu (Gu’an) Technology Co., Ltd., Langfang (CN)

(72) Inventors: Liang SU, Langfang (CN); Zhimin YAN, Langfang (CN); Fengjie JIN, Langfang (CN)

(73) Assignee: Yungu (Gu’an) Technology Co., Ltd., Langfang (CN)

(21) Appl. No.: 19/450,640

(22) Filed: Jan. 15, 2026

Related U.S. Application Data
(63) Continuation of application No. PCT/CN2024/073503, filed on Jan. 22, 2024.

(30) Foreign Application Priority Data
Jul. 20, 2023 (CN) 202310897791.1

(51) Int. Cl. C09K 11/56; C09K 11/54; C09K 11/88; C09K 113/00; H10K 50/115; H10K 50/15; H10K 50/165; H10K 50/81; H10K 50/82; H10K 85/10

(52) U.S. Cl. CPC C09K 11/565; C09K 11/54; C09K 11/883; H10K 50/115; H10K 50/15; H10K 50/165; H10K 50/81; H10K 50/82; H10K 85/1135; C09K 2113/00

(57) ABSTRACT

The present application relates to a quantum dot and an electroluminescent device. The quantum dot includes a core, at least one set of inner shell layer units sequentially coated on the surface of the core, and an outer shell layer; each set of inner shell layer units includes a first inner shell layer and a second inner shell layer; the band gap of the first inner shell layer is greater than the band gap of the core and the band gap of the second inner shell layer; the band gap of the outer shell layer is greater than or equal to the band gap of the first inner shell layer. Through the design of the size and core-shell structure of the quantum dot, the present application achieves that the photoluminescence properties of the quantum dot are more resistant to the destructive effects of accumulated charges.

### CROSS-REFERENCE TO RELATED APPLICATIONS

The present application claims priority to PCT Patent Application No. PCT/CN2024/073503, entitled “Quantum Dots and Electroluminescent Devices” and filed on Jan. 22, 2024, which claims priority to Chinese Patent Application No. 202310897791.1 filed on Jul. 20, 2023, both of which are incorporated herein by reference in their entireties.

### FIELD

The present application relates to the field of display technology, and in particular, to quantum dots and an electroluminescent device.

### BACKGROUND

Active Matrix Quantum Light-Emitting Diode (AMQLED) display technology is widely regarded as the next-generation display technology due to its characteristics such as wide color gamut, high color purity, high brightness, low power consumption, high response speed, and flexibility.

Currently, red, green, and blue QLEDs are approaching or have reached theoretical limits in terms of efficiency. Regarding lifetime, the performance of red and green QLEDs is already sufficient to meet commercial requirements, with the only bottleneck being the insufficient lifetime of blue QLEDs. Therefore, solving the lifetime issue of blue QLEDs is of great significance for promoting the commercialization of QLEDs.

### SUMMARY

Based on this, it is necessary to provide quantum dots and an electroluminescent device to address the problem of how to improve the lifetime of blue QLEDs.

A quantum dot, including a core, at least one set of inner shell units and an outer shell sequentially coating the surface of the core;
the material of the core is ZnxCd1-xS, where x is 0 to 1; the size of the core is at least 3 nm;
each set of the inner shell units includes a first inner shell and a second inner shell in a direction away from the core, the band gap of the first inner shell being greater than the band gap of the core and the band gap of the second inner shell;
the band gap of the outer shell is greater than or equal to the band gap of the first inner shell.

In the quantum dots of the present application, the core has a larger size, which can reduce the destructive impact of accumulated charges on exciton transitions in the quantum dots under conditions of QLED charge accumulation, thereby maintaining high photoluminescence quantum yield for a longer time and helping to improve QLED lifetime; the band gap of the first inner shell being greater than the band gap of the core can effectively confine electrons or holes at the surface of the core, enabling the quantum dots of the present application to have high photoluminescence quantum yield; the band gap of the first inner shell being greater than the band gap of the second inner shell enables charge carriers to enter the quantum dots more efficiently through a tunneling process, thereby improving the charge balance level of the QLED and helping to achieve high device efficiency; the outer shell has the widest band gap, enabling the quantum dots to have high photoluminescence quantum yield and stability, further improving QLED lifetime. Therefore, through the design of the quantum dot size and core-shell structure, the present application achieves quantum dots whose photoluminescence characteristics are more resistant to the destructive impact of accumulated charges, thereby enabling QLEDs to have higher lifetime.

The electroluminescent device of the present application demonstrates high efficiency and lifetime, as verified experimentally, making it beneficial for widespread application.

### BRIEF DESCRIPTION OF THE DRAWINGS

FIG. 1 is a schematic structural diagram of a quantum dot according to an embodiment of the present application;

FIG. 2 is a schematic band gap diagram of a quantum dot according to an embodiment of the present application;

FIG. 3 is a schematic structural diagram of a quantum dot according to another embodiment of the present application;

FIG. 4 is a schematic structural diagram of an electroluminescent device according to an embodiment of the present application;

FIG. 5 is a CE-L curve diagram of QLEDs according to Example 8 and Comparative Example 2 of the present application;

FIG. 6 is an L-T curve diagram of QLEDs according to Example 8 and Comparative Example 2 of the present application.

### DETAILED DESCRIPTION OF THE EMBODIMENTS

According to related research, blue QLEDs have a significant charge accumulation problem, where accumulated charges may exist in the hole transport layer, the light-emitting layer, or the electron transport layer. These accumulated charges cause complex physical & chemical processes and are a key factor leading to the low lifetime of blue QLEDs. To address this, the present application proposes quantum dots and an electroluminescent device that can prevent the photoluminescence quantum yield (PLQY) of the quantum dots from decreasing too rapidly, thereby improving the lifetime of blue QLEDs.

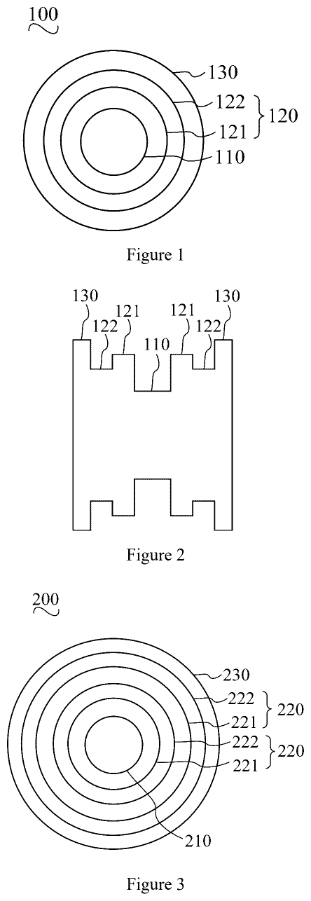

Please refer to FIG. 1 and FIG. 2. A quantum dot 100 according to an embodiment of the present application includes a core 110, at least one set of inner shell units 120, and an outer shell 130 sequentially coating the surface of the core 110. In this embodiment, the number of sets of inner shell units 120 is one. In one embodiment, the material of the core 110 is ZnxCd1-xS, where x is 0 to 1; the size of the core 110 is at least 3 nm, the size is the average core diameter. In one embodiment, x is greater than 0 and less than 1. The “size” in the present application generally refers to the diameter. In the quantum dot 100 of this embodiment, the core 110 has a larger size, which can reduce the destructive impact of accumulated charges on exciton transitions in the quantum dots under conditions of QLED charge accumulation, thereby maintaining high photoluminescence quantum yield for a longer time and helping to improve QLED lifetime.

In one embodiment, the band gap of the first inner shell 121 is greater than the band gap of the core 110 and also greater than the band gap of the second inner shell 122 ‘ [symbol] ’ the band gap of the first inner shell 121 is greater than that of the core 110 and greater than that of the second inner shell 122. In one embodiment, the band gap of the first inner shell 121 being greater than the band gap of the core 110 can effectively confine electrons or holes at the surface of the core 110, enabling the quantum dot 100 of this embodiment to have high photoluminescence quantum yield, which can reach over 80%. Furthermore, the band gap of the first inner shell 121 being greater than the band gap of the second inner shell 122 enables charge carriers to enter the quantum dot 100 more efficiently through a tunneling process, thereby improving the charge balance level of the QLED and helping to achieve high device efficiency.

Additionally, the band gap of the outer shell 130 is greater than or equal to the band gap of the first inner shell 121. In this embodiment, the band gap of the outer shell 130 being greater than or equal to the band gap of the first inner shell 121 enables the quantum dots to have high photoluminescence quantum yield and stability, further improving QLED lifetime. Herein, stability refers to photostability and chemical stability.

On the basis of the foregoing embodiments, the size of the core 110 is 3 nm to 15 nm. At this time, the size of the core 110 can be maintained at a relatively large level, and the destructive effect of accumulated charges on the exciton transition of quantum dots can be reduced in the case of QLED charge accumulation, thereby maintaining a high photoluminescence quantum yield for a longer time, which helps to improve the lifetime of the QLED; at the same time, it can also avoid the excessive size of the core 110 affecting the wavelength requirements and the selection of the inner shell unit 120 and the outer shell 130. Further, the size of the core 110 may be, for example, 3 nm, 4 nm, 5 nm, 6 nm, 7 nm, 8 nm, 9 nm, 10 nm, 11 nm, 12 nm, 13 nm, 14 nm, or 15 nm.

On the basis of the foregoing embodiments, the size of the quantum dot 100 is 10 nm to 30 nm. The size of the quantum dot 100 is the sum of the size of the core 110, the thickness of at least one set of inner shell units 120, and the thickness of the outer shell 130. In this configuration, the quantum dot 100 can have more stable luminous efficiency and effective charge injection capability under charge accumulation conditions.

On the basis of the foregoing embodiments, the thicknesses of the first inner shell 121, the second inner shell 122, and the outer shell 130 are all 0.35 nm to 3.5 nm. The first inner shell 121, the second inner shell 122, and the outer shell 130 within the above thickness range can repair defects on the surface of the core 110. Further, the thicknesses of the first inner shell 121, the second inner shell 122, and the outer shell 130 may be, for example, 0.35 nm, 0.7 nm, 1.05 nm, 1.4 nm, 1.75 nm, 2.1 nm, 2.45 nm, 2.8 nm, 3.15 nm, or 3.5 nm.

On the basis of the foregoing embodiments, the material of the core 110 is ZnxCd1-xS, where x is 0.2 to 0.7. At this time, the band gap of the core 110 can be reasonably matched with the band gaps of the inner shell unit 120 and the outer shell 130, which helps to achieve high device efficiency and device lifetime. Further, x in the material of the core 110 may be 0.2, 0.3, 0.4, 0.5, 0.6, or 0.7.

On the basis of the foregoing embodiments, the material of the core 110 is ZnxCd1-xS, where x is 0.4 to 0.6. At this time, the band gap of the core 110 matches best with the band gaps of the inner shell unit 120 and the outer shell 130, which helps to achieve higher device efficiency and device lifetime.

On the basis of the foregoing embodiments, the material of the first inner shell 121 is selected from at least one of ZnyCd1-yS and ZnSeS, where y is x to 1, and x<y<1; the material of the second inner shell 122 is selected from at least one of ZnzCd1-zS, ZnCdSe, and ZnCdSeS, where z<y; the material of the outer shell 130 is selected from at least one of ZnCdS, ZnSeS, and ZnS. In the quantum dot 100 of this embodiment, the lattice of the materials of the core 110, the first inner shell 121, the second inner shell 122, and the outer shell 130 are matched, which can prevent the collapse of the quantum dot 100.

On the basis of the foregoing embodiments, the material of the second inner shell 122 is ZnzCd1-zS, where z>x. At this time, the band gap of the second inner shell 122 is greater than the band gap of the core 110, and the second inner shell 122 can still function to confine excitons within the core, which is beneficial for obtaining high luminous efficiency.

On the basis of the foregoing embodiments, the difference between the band gap of the first inner shell 121 and the band gap of the core 110 is 0.2 eV to 1 eV, the difference between the band gap of the first inner shell 121 and the band gap of the second inner shell 122 is 0.1 eV to 1 eV, and the difference between the band gap of the outer shell 130 and the band gap of the first inner shell 121 is 0.1 eV to 1 eV. In this configuration, the band gaps of the core 110, the first inner shell 121, the second inner shell 122, and the outer shell 130 are reasonably matched, which helps to achieve higher device efficiency and device lifetime.

On the basis of the foregoing embodiments, the surface of the quantum dot 100 has ligands, and the surface ligands of the quantum dot 100 may be including but not limited to amino, organic phosphorus, carboxylic acid, or thiol. The surface ligands can enable the quantum dots of the present application to have high PLQY and solubility.

On the basis of the foregoing embodiments, the materials of the core 110, the first inner shell 121, the second inner shell 122, and the outer shell 130 are Zn0.5Cd0.5S, Zn0.8Cd0.2S, Zn0.6Cd0.4S, and ZnS, respectively. It has been experimentally verified that the quantum dot structure of this embodiment can enable electroluminescent devices to have high efficiency and lifetime.

On the basis of the foregoing embodiments, the materials of the core 110, the first inner shell 121, the second inner shell 122, and the outer shell 130 are Zn0.4Cd0.6S, ZnSeS, ZnCdSe, and ZnS, respectively. It has been experimentally verified that the quantum dot structure of this embodiment can enable electroluminescent devices to have high efficiency and lifetime.

On the basis of the foregoing embodiments, the materials of the core 110, the first inner shell 121, the second inner shell 122, and the outer shell 130 are Zn0.2Cd0.8S, ZnSeS, ZnCdSe, and ZnS, respectively. It has been experimentally verified that the quantum dot structure of this embodiment can enable electroluminescent devices to have high efficiency and lifetime.

On the basis of the foregoing embodiments, the materials of the core 110, the first inner shell 121, the second inner shell 122, and the outer shell 130 are Zn0.2Cd0.8S, Zn0.8Cd0.2S, ZnCdSe, and ZnS, respectively. Experimental verification has shown that the quantum dot structure of this embodiment can enable electroluminescent devices to have high efficiency and lifetime.

On the basis of the foregoing embodiments, the materials of the core 110, the first inner shell 121, the second inner shell 122, and the outer shell 130 are Zn0.6Cd0.4S, ZnSeS, ZnCdSe, and ZnS, respectively. Experimental verification has shown that the quantum dot structure of this embodiment can enable electroluminescent devices to have high efficiency and lifetime.

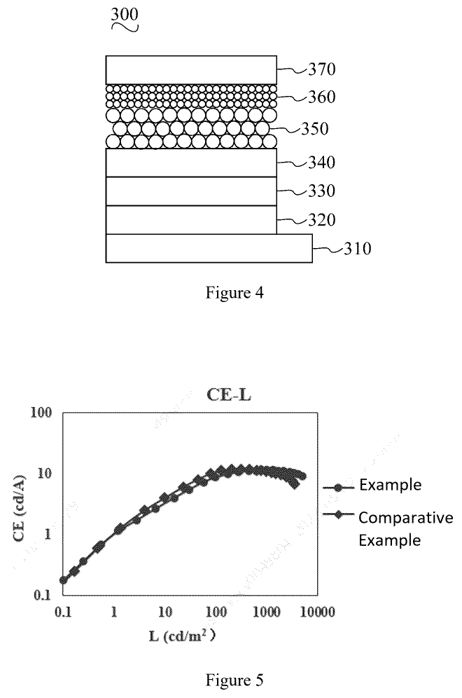

On the basis of the foregoing embodiment, the materials of the core 110, the first inner shell layer 121, the second inner shell layer 122, and the outer shell layer 130 are Zn0.7Cd0.3S, ZnSeS, ZnCdSe, and ZnS, respectively. Experimental verification has shown that the quantum dot structure of this embodiment can enable the electroluminescent device to have high efficiency and long lifetime. In the above embodiment, the number of sets of inner shell layer units is one; however, in the quantum dots of the present application, the number of sets of inner shell layer units is not limited thereto and may also be two or more. Please refer to FIG. 3. A quantum dot 200 according to another embodiment of the present application includes a core 210, an inner shell layer unit 220 sequentially coating the surface of the core 210, and an outer shell layer 230. The inner shell layer unit 220 includes a first inner shell layer 221 and a second inner shell layer 222 arranged in a direction away from the core 210. Different from the quantum dot 100 of the foregoing embodiment, in the quantum dot 200 of this embodiment, the number of sets of inner shell layer units 220 is two. The material selection for the first inner shell layer 221 and the second inner shell layer 222 of each set of inner shell layer units 220 still follows the aforementioned selection, but the thickness should be reduced; for example, the total thickness of the two sets of inner shell layer units 220 is the same as the total thickness of one set of inner shell layer units in the foregoing embodiment. On the basis of the foregoing embodiment, the materials of the core 210, the first inner shell layer 221, the second inner shell layer 222, the first inner shell layer 221, the second inner shell layer 222, and the outer shell layer 230 in the direction from the core 210 to the outer shell layer 230 are Zn0.5Cd0.5S, Zn0.8Cd0.2S, Zn0.6Cd0.4S, Zn0.8Cd0.2S, Zn0.6Cd0.4S, and ZnS, respectively. Experimental verification has shown that the quantum dot structure of this embodiment can enable the electroluminescent device to have high efficiency and long lifetime. In the quantum dot 200 of this embodiment, the core 210 can reduce the destructive effect of accumulated charges on exciton transitions in quantum dots under QLED charge accumulation conditions, thereby maintaining a high photoluminescence quantum yield for a longer time, which helps improve QLED lifetime. The bandgap of the first inner shell layer 221 being greater than that of the core 210 can effectively confine electrons or holes at the surface of the core 210, enabling the quantum dot 200 of this embodiment to have a high photoluminescence quantum yield, which can reach over 80%. Moreover, the bandgap of the first inner shell layer 221 being greater than that of the second inner shell layer 222, combined with the use of two sets of thinner inner shell layer units 220, can further enable charge carriers to enter the quantum dot 200 more effectively through tunneling processes, thereby improving the charge balance level of the QLED and contributing to high device efficiency. The bandgap of the outer shell layer 230 being greater than or equal to that of the first inner shell layer 221 can provide the quantum dot with high photoluminescence quantum yield and stability, further enhancing QLED lifetime. Applying the embodiments of the present application to quantum dots, the core has a larger size, which can reduce the destructive effect of accumulated charges on exciton transitions in quantum dots under QLED charge accumulation conditions, thereby maintaining a high photoluminescence quantum yield for a longer time and helping improve QLED lifetime. The bandgap of the first inner shell layer being greater than that of the core can effectively confine electrons or holes at the surface of the core, giving the quantum dots of the present application a high photoluminescence quantum yield. The bandgap of the first inner shell layer being greater than that of the second inner shell layer enables charge carriers to enter the quantum dot more effectively through tunneling processes, thereby improving the charge balance level of the QLED and contributing to high device efficiency. The outer shell layer has the widest bandgap, providing the quantum dot with high photoluminescence quantum yield and stability, further enhancing QLED lifetime. Therefore, through the design of the quantum dot size and core-shell structure, the present application achieves quantum dots whose photoluminescence characteristics are more resistant to the destructive effects of accumulated charges, thereby giving QLEDs a longer lifetime. An electroluminescent device according to one embodiment includes a quantum dot light-emitting layer, which includes any of the aforementioned quantum dots. The electroluminescent device may be a normal-type device or an inverted-type device, which is not limited by the present application. Please refer to FIG. 4. An electroluminescent device 300 according to one embodiment includes a substrate 310, an anode 320, a hole injection layer (HIL) 330, a hole transport layer (HTL) 340, a quantum dot light-emitting layer 350, an electron transport layer (ETL) 360, and a cathode 370, which are sequentially arranged. The material of the anode 320 may be, for example, ITO or IZO, etc. The material of the hole injection layer 330 may be, for example, PEDOT:PSS, phosphomolybdic acid, or phosphotungstic acid, etc. The material of the hole transport layer 340 is selected from at least one of TFB, PVK, Poly-TPD, NPB, CBP, TCTA, and NiO. The material of the electron transport layer 360 may be, for example, ZnO, doped ZnO (dopants including Al, Mg, Ga, Hf, N, P, or combinations thereof), or SnO2, etc. The material of the cathode 370 may be, for example, Al or Ag, etc. Experimental verification has shown that the electroluminescent device of the present application has high efficiency and long lifetime, which is beneficial for widespread application. With reference to the above embodiments, to make the embodiments of the present application more specific, clear, and easy to understand, examples of the embodiments of the present application are provided below. However, the content to be protected by the present application is not limited to Examples 1 to 14 below.

### Embodiment 1

This embodiment provides a quantum dot and a preparation method thereof. The materials of the core 110, the inner shell unit 120 (including the first inner shell 121 and the second inner shell 122), and the outer shell 130 are sequentially Zn0.5Cd0.5S/Zn0.8Cd0.2S/Zn0.6Cd0.4S/ZnS. The diameter of the quantum dot 100 of this embodiment is 14.6 nm, the diameter of the core 110 is 5 nm, and the thicknesses of the first inner shell 121, the second inner shell 122, and the outer shell 130 are sequentially 2.1 nm, 1.5 nm, and 1.2 nm.

The preparation steps of the quantum dot of this embodiment are as follows:
1) Add 4 mmol of zinc acetate, 0.6 mmol of cadmium acetate, and 10 ml of oleic acid into a 100 ml three-necked flask, introduce nitrogen gas, heat to 180° C. and stir until the solution becomes clear and transparent, then add 20 ml of octadecene, and raise the temperature to 320° C.;
2) Dissolve 1 mmol of sulfur powder in 1 ml of trioctylphosphine, then quickly inject it into the solution described in 1), react for 25 minutes to obtain a quantum dot core solution;
3) Dissolve 0.5 mmol of sulfur powder in 0.5 ml of trioctylphosphine, dissolve 0.15 mmol of cadmium acetate in 1.5 ml of oleic acid, then mix the two and slowly (0.07 ml/min) inject them into the quantum dot core solution described in 2) to grow the first inner shell, react for 30 minutes;
4) Dissolve 0.25 mmol of sulfur powder in 0.25 ml of trioctylphosphine, dissolve 0.1 mmol of cadmium acetate in 1 ml of oleic acid, then mix the two and slowly (0.05 ml/min) inject them into the solution described in 3) to grow the second inner shell, react for 20 minutes;
5) Dissolve 0.2 mmol of sulfur powder in 0.2 ml of trioctylphosphine, then slowly (0.02 ml/min) inject it into the solution described in 4) to grow the outer shell, react for 10 minutes;
6) Cool the solution described in 5) to room temperature, add excess acetone to precipitate the quantum dots, then remove the acetone and add n-octane to dissolve to obtain a quantum dot solution. This process is repeated 3 times to obtain a pure quantum dot solution.

### Embodiment 2

This embodiment provides a quantum dot and a preparation method thereof. The quantum dot 100 of this embodiment differs from the quantum dot 100 of Embodiment 1 in that the materials of the core 110, the first inner shell 121, the second inner shell 122, and the outer shell 130 are sequentially Zn0.4Cd0.6S/ZnSeS/ZnCdSe/ZnS. The diameter of the quantum dot 100 of this embodiment is 14.1 nm, the diameter of the core 110 is 4.5 nm, and the thicknesses of the first inner shell 121, the second inner shell 122, and the outer shell 130 are sequentially 2.1 nm, 1.5 nm, and 1.2 nm.

The preparation steps of the quantum dot of this embodiment are as follows:
1) Add 3 mmol of zinc acetate, 0.7 mmol of cadmium acetate, and 10 ml of oleic acid into a 100 ml three-necked flask, introduce nitrogen gas, heat to 180° C. and stir until the solution becomes clear and transparent, then add 20 ml of octadecene, and raise the temperature to 320° C.;
2) Dissolve 1 mmol of sulfur powder in 1 ml of trioctylphosphine, then quickly inject it into the solution described in 1), react for 20 minutes to obtain a quantum dot core solution;
3) Dissolve 0.25 mmol of sulfur powder and 0.25 mmol of selenium powder in 0.5 ml of trioctylphosphine, then slowly (0.03 ml/min) inject it into the quantum dot core solution described in 2) to grow the first inner shell, react for 20 minutes;
4) Dissolve 0.25 mmol of selenium powder in 0.25 ml of trioctylphosphine, dissolve 0.1 mmol of cadmium acetate in 1 ml of oleic acid, then mix the two and slowly (0.05 ml/min) inject them into the solution described in 3) to grow the second inner shell, react for 20 minutes;
5) Dissolve 0.2 mmol of sulfur powder in 0.2 ml of trioctylphosphine, then slowly (0.02 ml/min) inject it into the solution described in 4) to grow the outer shell, react for 10 minutes;
6) Cool the solution described in 5) to room temperature, add excess acetone to precipitate the quantum dots, then remove the acetone and add n-octane to dissolve to obtain a quantum dot solution. This process is repeated 3 times to obtain a pure quantum dot solution.

### Embodiment 3

This embodiment provides a quantum dot and a preparation method thereof. The quantum dot 100 of this embodiment differs from the quantum dot 100 of Embodiment 1 in that the materials of the core 110, the first inner shell 121, the second inner shell 122, and the outer shell 130 are sequentially Zn0.2Cd0.8S/ZnSeS/ZnCdSe/ZnS. The diameter of the quantum dot 100 of this embodiment is 12.7 nm, the diameter of the core 110 is 3.1 nm, and the thicknesses of the first inner shell 121, the second inner shell 122, and the outer shell 130 are sequentially 2.1 nm, 1.5 nm, and 1.2 nm.

The preparation steps of the quantum dots in this embodiment are as follows:
1) Add 3 mmol of zinc acetate, 0.9 mmol of cadmium acetate, and 10 ml of oleic acid into a 100 ml three-neck flask, introduce nitrogen gas, heat to 180° C. and stir until the solution becomes clear and transparent, then add 20 ml of octadecene, and raise the temperature to 320° C.;
2) Dissolve 1 mmol of sulfur powder in 1 ml of trioctylphosphine, then rapidly inject it into the solution described in 1), react for 15 minutes to obtain a quantum dot core solution;
3) Dissolve 0.25 mmol of sulfur powder and 0.25 mmol of selenium powder in 0.5 ml of trioctylphosphine, then slowly (0.03 ml/min) inject it into the quantum dot core solution described in 2) to grow the first inner shell layer, react for 20 minutes;
4) Dissolve 0.25 mmol of selenium powder in 0.25 ml of trioctylphosphine, dissolve 0.1 mmol of cadmium acetate in 1 ml of oleic acid, then mix the two and slowly (0.05 ml/min) inject them into the solution described in 3) to grow the second inner shell layer, react for 20 minutes;
5) Dissolve 0.2 mmol of sulfur powder in 0.2 ml of trioctylphosphine, then slowly (0.02 ml/min) inject it into the solution described in 4) to grow the outer shell layer, react for 10 minutes;
6) Cool the solution described in 5) to room temperature, add excess acetone to precipitate the quantum dots, then remove the acetone and add n-octane to dissolve to obtain a quantum dot solution. This process is repeated 3 times to obtain a pure quantum dot solution.

### Embodiment 4

This embodiment provides a quantum dot and its preparation method. The difference between the quantum dot 100 of this embodiment and the quantum dot 100 of Embodiment 1 is that the materials of the core 110, the first inner shell layer 121, the second inner shell layer 122, and the outer shell layer 130 are sequentially Zn0.2Cd0.8S/Zn0.8Cd0.2S/ZnCdSe/ZnS. The diameter of the quantum dot 100 of this embodiment is 12.7 nm, the diameter of the core 110 is 3.1 nm, and the thicknesses of the first inner shell layer 121, the second inner shell layer 122, and the outer shell layer 130 are sequentially 2.1 nm, 1.5 nm, and 1.2 nm.

The preparation steps of the quantum dots in this embodiment are as follows:
1) Add 3 mmol of zinc acetate, 0.9 mmol of cadmium acetate, and 10 ml of oleic acid into a 100 ml three-neck flask, introduce nitrogen gas, heat to 180° C. and stir until the solution becomes clear and transparent, then add 20 ml of octadecene, and raise the temperature to 320° C.;
2) Dissolve 1 mmol of sulfur powder in 1 ml of trioctylphosphine, then rapidly inject it into the solution described in 1), react for 25 minutes to obtain a quantum dot core solution;
3) Dissolve 0.5 mmol of sulfur powder in 0.5 ml of trioctylphosphine, dissolve 0.15 mmol of cadmium acetate in 1.5 ml of oleic acid, then mix the two and slowly (0.07 ml/min) inject them into the quantum dot core solution described in 2) to grow the first inner shell layer, react for 30 minutes;
4) Dissolve 0.25 mmol of selenium powder in 0.25 ml of trioctylphosphine, dissolve 0.1 mmol of cadmium acetate in 1 ml of oleic acid, then mix the two and slowly (0.05 ml/min) inject them into the solution described in 3) to grow the second inner shell layer, react for 20 minutes;
5) Dissolve 0.2 mmol of sulfur powder in 0.2 ml of trioctylphosphine, then slowly (0.02 ml/min) inject it into the solution described in 4) to grow the outer shell layer, react for 10 minutes;
6) Cool the solution described in 5) to room temperature, add excess acetone to precipitate the quantum dots, then remove the acetone and add n-octane to dissolve to obtain a quantum dot solution. This process is repeated 3 times to obtain a pure quantum dot solution.

### Embodiment 5

This embodiment provides a quantum dot and its preparation method. The difference between the quantum dot 100 of this embodiment and the quantum dot of Embodiment 2 is that x is 0.6. The diameter of the quantum dot 100 of this embodiment is 15.3 nm, the diameter of the core 110 is 5.7 nm, and the thicknesses of the first inner shell layer 121, the second inner shell layer 122, and the outer shell layer 130 are sequentially 2.1 nm, 1.5 nm, and 1.2 nm.

The preparation steps of the quantum dots in this embodiment are as follows:
1) Add 3 mmol of zinc acetate, 0.5 mmol of cadmium acetate, and 10 ml of oleic acid into a 100 ml three-neck flask, introduce nitrogen gas, heat to 180° C. and stir until the solution becomes clear and transparent, then add 20 ml of octadecene, and raise the temperature to 320° C.;
2) Dissolve 1 mmol of sulfur powder in 1 ml of trioctylphosphine, then rapidly inject it into the solution described in 1), react for 20 minutes to obtain a quantum dot core solution;
3) Dissolve 0.25 mmol of sulfur powder and 0.25 mmol of selenium powder in 0.5 ml of trioctylphosphine, then slowly (0.03 ml/min) inject it into the quantum dot core solution described in 2) to grow the first inner shell layer, react for 20 minutes;
4) Dissolve 0.25 mmol of selenium powder in 0.25 ml of trioctylphosphine, dissolve 0.1 mmol of cadmium acetate in 1 ml of oleic acid, then mix the two and slowly (0.05 ml/min) inject them into the solution described in 3) to grow the second inner shell layer, react for 20 minutes;
5) Dissolve 0.2 mmol of sulfur powder in 0.2 ml of trioctylphosphine, then slowly (0.02 ml/min) inject it into the solution described in 4) to grow the outer shell layer, react for 10 minutes;
6) Cool the solution described in 5) to room temperature, add excess acetone to precipitate the quantum dots, then remove the acetone and add n-octane to dissolve to obtain a quantum dot solution. This process is repeated 3 times to obtain a pure quantum dot solution.

### Embodiment 6

This embodiment provides a quantum dot and its preparation method. The difference between the quantum dot 100 of this embodiment and the quantum dot of Embodiment 2 is that x is 0.7. The diameter of the quantum dot 100 of this embodiment is 16.1 nm, the diameter of the core 110 is 6.5 nm, and the thicknesses of the first inner shell layer 121, the second inner shell layer 122, and the outer shell layer 130 are sequentially 2.1 nm, 1.5 nm, and 1.2 nm.

The preparation steps of the quantum dots in this embodiment are as follows:
1) Add 3 mmol of zinc acetate, 0.5 mmol of cadmium acetate, and 10 ml of oleic acid into a 100 ml three-neck flask, introduce nitrogen gas, heat to 180° C. and stir until the solution becomes clear and transparent, then add 20 ml of octadecene, and raise the temperature to 320° C.;
2) Dissolve 1 mmol of sulfur powder in 1 ml of trioctylphosphine, then rapidly inject it into the solution described in 1), react for 20 minutes to obtain a quantum dot core solution;
3) Dissolve 0.25 mmol of sulfur powder and 0.25 mmol of selenium powder in 0.5 ml of trioctylphosphine, then slowly (0.03 ml/min) inject it into the quantum dot core solution described in 2) to grow the first inner shell layer, react for 20 minutes;
4) Dissolve 0.25 mmol of selenium powder in 0.25 ml of trioctylphosphine, dissolve 0.1 mmol of cadmium acetate in 1 ml of oleic acid, then mix the two and slowly (0.05 ml/min) inject them into the solution described in 3) to grow the second inner shell layer, react for 20 minutes;
5) Dissolve 0.2 mmol of sulfur powder in 0.2 ml of trioctylphosphine, then slowly (0.02 ml/min) inject it into the solution described in 4) to grow the outer shell layer, react for 10 minutes.

The preparation steps of the quantum dots in this embodiment are as follows:
1) Add 3.5 mmol of zinc acetate, 0.4 mmol of cadmium acetate, and 10 ml of oleic acid into a 100 ml three-neck flask, introduce nitrogen gas, heat to 180° C. and stir until the solution becomes clear and transparent, then add 20 ml of octadecene, and raise the temperature to 320° C.;
2) Dissolve 1 mmol of sulfur powder in 1 ml of trioctylphosphine, then quickly inject it into the solution described in 1), react for 20 minutes to obtain a quantum dot core solution;
3) Dissolve 0.25 mmol of sulfur powder and 0.25 mmol of selenium powder in 0.5 ml of trioctylphosphine, then slowly (0.03 ml/min) inject it into the quantum dot core solution described in 2) to grow the first inner shell layer, react for 20 minutes;
4) Dissolve 0.25 mmol of selenium powder in 0.25 ml of trioctylphosphine, dissolve 0.1 mmol of cadmium acetate in 1 ml of oleic acid, then mix the two and slowly (0.05 ml/min) inject into the solution described in 3) to grow the second inner shell layer, react for 20 minutes;
5) Dissolve 0.2 mmol of sulfur powder in 0.2 ml of trioctylphosphine, then slowly (0.02 ml/min) inject it into the solution described in 4) to grow the outer shell layer, react for 10 minutes;
6) Cool the solution described in 5) to room temperature, add excess acetone to precipitate the quantum dots, then remove the acetone and add n-octane to dissolve to obtain a quantum dot solution. This process is repeated 3 times to obtain a pure quantum dot solution.

### Embodiment 7

The structure of the quantum dot 200 in this embodiment is shown in FIG. 2, including a core 210, two sets of inner shell units 220 sequentially coating the surface of the core 210, and an outer shell 230. Each set of inner shell units 220 includes a first inner shell 221 and a second inner shell 222. Among them, the materials of the core 210, the first inner shell 221, the second inner shell 222, the first inner shell 221, the second inner shell 222, and the outer shell 230 from the core 210 outward to the outer shell 230 are sequentially Zn0.5Cd0.5S/Zn0.8Cd0.2S/Zn0.6Cd0.4S/Zn0.8Cd0.2S/Zn0.6Cd0.4S/ZnS. The diameter of the quantum dot 200 in this embodiment is 14.6 nm, the diameter of the core 210 is 5 nm, the thickness of the first inner shell 221 is 1.05 nm, the thickness of the second inner shell is 0.75 nm, the thickness of the first inner shell 221 is 1.05 nm, the thickness of the second inner shell 222 is 0.75 nm, and the thickness of the outer shell 230 is 1.2 nm. The preparation steps of the quantum dots in this embodiment are as follows:
1) Add 6 mmol of zinc acetate, 0.6 mmol of cadmium acetate, and 10 ml of oleic acid into a 100 ml three-neck flask, introduce nitrogen gas, heat to 180° C. and stir until the solution becomes clear and transparent, then add 20 ml of octadecene, and raise the temperature to 320° C.;
2) Dissolve 1 mmol of sulfur powder in 1 ml of trioctylphosphine, then quickly inject it into the solution described in 1), react for 25 minutes to obtain a quantum dot core solution;
3) Dissolve 0.25 mmol of sulfur powder in 0.25 ml of trioctylphosphine, dissolve 0.07 mmol of cadmium acetate in 0.7 ml of oleic acid, then mix the two and slowly (0.04 ml/min) inject into the quantum dot core solution described in 2) to grow the first inner shell layer, react for 15 minutes;
4) Dissolve 0.12 mmol of sulfur powder in 0.15 ml of trioctylphosphine, dissolve 0.05 mmol of cadmium acetate in 0.5 ml of oleic acid, then mix the two and slowly (0.04 ml/min) inject into the solution described in 3) to grow the second inner shell layer, react for 10 minutes;
5) Dissolve 0.2 mmol of sulfur powder in 0.2 ml of trioctylphosphine, then slowly (0.02 ml/min) inject it into the solution described in 4) to grow the outer shell layer, react for 10 minutes;
6) Dissolve 0.12 mmol of sulfur powder in 0.15 ml of trioctylphosphine, dissolve 0.05 mmol of cadmium acetate in 0.5 ml of oleic acid, then mix the two and slowly (0.04 ml/min) inject into the solution described in 3) to grow the second inner shell layer, react for 10 minutes;
7) Dissolve 0.2 mmol of sulfur powder in 0.2 ml of trioctylphosphine, then slowly (0.02 ml/min) inject it into the solution described in 4) to grow the outer shell layer, react for 10 minutes;
8) Cool the solution described in 7) to room temperature, add excess acetone to precipitate the quantum dots, then remove the acetone and add n-octane to dissolve to obtain a quantum dot solution. This process is repeated 3 times to obtain a pure quantum dot solution.

### Embodiment 8 to Embodiment 14

The quantum dots from Embodiment 1 to Embodiment 7 are respectively used to fabricate QLEDs of Embodiment 8 to Embodiment 14, with the steps as follows:
1) Clean the patterned ITO glass substrate, dry it, and perform UVO treatment;
2) Deposit PEDOT:PSS as the HIL on the ITO substrate using a solution method, with a thickness of 40 nm;
3) Deposit TFB as the HTL on the HIL using a solution method, with a thickness of 30 nm;
4) Deposit the quantum dot solutions from Embodiment 1 to Embodiment 7 as the EML on the HTL using a solution method, with a thickness of 40 nm;
5) Deposit Mg-doped ZnO nanoparticles as the ETL on the EML using a solution method, with a thickness of 50 nm;
6) Deposit Ag as the cathode on the ETL using an evaporation method, with a thickness of 100 nm.

### Comparative Example 1

This comparative example is a comparative example to Embodiment 1, providing a quantum dot and its preparation method. The difference from the quantum dot of Embodiment 1 is: the material of the core is Zn0.2Cd0.8S, the diameter of the core is 2.5 nm, and the diameter of the quantum dot is 12.1 nm.

The preparation steps of the quantum dots in this comparative example are as follows:
1) Add 3 mmol of zinc acetate, 0.9 mmol of cadmium acetate, and 10 ml of oleic acid into a 100 ml three-neck flask, introduce nitrogen gas, heat to 180° C. and stir until the solution becomes clear and transparent, then add 20 ml of octadecene and raise the temperature to 320° C.;
2) Dissolve 1 mmol of sulfur powder in 1 ml of trioctylphosphine, then quickly inject it into the solution described in 1), react for 15 minutes to obtain a quantum dot core solution;
3) Dissolve 0.5 mmol of sulfur powder in 0.5 ml of trioctylphosphine, dissolve 0.15 mmol of cadmium acetate in 1.5 ml of oleic acid, then mix the two and slowly (0.07 ml/min) inject them into the quantum dot core solution described in 2) to grow the first inner shell layer, react for 30 minutes;
4) Dissolve 0.25 mmol of sulfur powder in 0.25 ml of trioctylphosphine, dissolve 0.1 mmol of cadmium acetate in 1 ml of oleic acid, then mix the two and slowly (0.05 ml/min) inject them into the solution described in 3) to grow the second inner shell layer, react for 20 minutes;
5) Dissolve 0.2 mmol of sulfur powder in 0.2 ml of trioctylphosphine, then slowly (0.02 ml/min) inject it into the solution described in 4) to grow the outer shell layer, react for 10 minutes;
6) Cool the solution described in 5) to room temperature, add excess acetone to precipitate the quantum dots, then remove the acetone and add n-octane to dissolve to obtain a quantum dot solution. This process is repeated 3 times to obtain a purified quantum dot solution.

### Comparative Example 2

The quantum dots from Comparative Example 1 are used to fabricate the QLED of Comparative Example 2, with the following steps:
1) Clean the patterned ITO glass substrate, dry it, and perform UVO treatment;
2) Deposit PEDOT:PSS as the HIL on the ITO substrate using a solution method, with a thickness of 40 nm;
3) Deposit TFB as the HTL on the HIL using a solution method, with a thickness of 30 nm;
4) Deposit the quantum dots from Comparative Example 1 as the EML on the HTL using a solution method, with a thickness of 40 nm;
5) Deposit Mg-doped ZnO nanoparticles as the ETL on the EML using a solution method, with a thickness of 50 nm;
6) Deposit Ag as the cathode on the ETL using an evaporation method, with a thickness of 100 nm.

### Performance Testing:

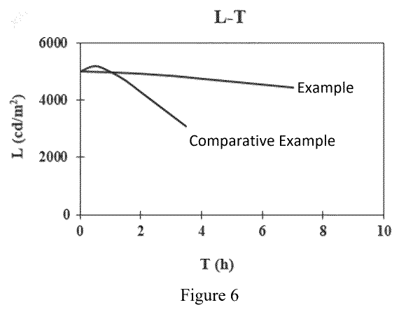

The QLEDs of Example 8 to Example 14 and Comparative Example 2 are subjected to performance testing. The testing methods are as follows, and the test results are shown in Table 1, FIG. 5, and FIG. 6.

CE-L Curve: Obtained by performing IVL (current-voltage-luminance) testing on the QLED; CE is current efficiency, with the unit cd/A; L is luminance, with the unit cd/m²;

L-T Curve: Obtained by performing lifetime testing on the QLED; L is luminance, T is time; generally, a constant current source is used to input current to the QLED, and the curve of its luminance changing over time is recorded; common lifetime parameters include T95, which represents the time it takes for the QLED's luminance to decay from the initial value to 95% of the initial value.

TABLE 1
Performance test results of QLEDs for Example
8 to Example 14 and Comparative Example 2

| Example/Comparative | | |
|---|---|---|
| Example | Max. CE (cd/A) | T95 (h) @50 mA/cm² |
| Example 8 | 11.5 | 6.7 |
| Example 9 | 10.6 | 5.5 |
| Example 10 | 10.9 | 3.2 |
| Example 11 | 10.5 | 3.5 |
| Example 12 | 11.2 | 7.0 |
| Example 13 | 11.6 | 6.5 |
| Example 14 | 9.8 | 5.8 |
| Comparative Example 2 | 11.3 | 1.5 |

As can be seen from Table 1, the QLEDs of Example 8 to Example 14 have relatively high efficiency and lifetime, indicating that the quantum dot structure of the present application can enable electroluminescent devices to have high efficiency and lifetime.

As can be seen from FIG. 5, the efficiency of the QLEDs of Example 8 and Comparative Example 2 is comparable; as can be seen from FIG. 6, compared to the QLED of Comparative Example 2, the lifetime of the QLED of Example 8 is significantly increased, indicating that the quantum dot structure of the present application can effectively improve device lifetime.

The various technical features of the embodiments described above can be combined arbitrarily. For the sake of brevity, not all possible combinations of the technical features in the above embodiments are described. However, as long as there is no contradiction in the combination of these technical features, they should be considered within the scope described in this specification.

The embodiments described above only express several implementations of the present application. Their descriptions are relatively specific and detailed, but should not be construed as limiting the scope of the disclosed patent. It should be pointed out that for those of ordinary skill in the art, without departing from the concept of the present application, several modifications and improvements can be made, all of which fall within the protection scope of the present application. Therefore, the protection scope of the patent of the present application shall be subject to the appended claims.

1. A quantum dot, the quantum dot comprising a core, at least one set of inner shell units sequentially coated on the surface of the core, and an outer shell;
the material of the core is ZnₓCd₁₋ₓS, where x is 0 to 1; the size of the core is at least 3 nm;
each set of the inner shell units comprises a first inner shell and a second inner shell along the direction away from the core, the band gap of the first inner shell being greater than the band gap of the core and the band gap of the second inner shell;
the band gap of the outer shell is greater than or equal to the band gap of the first inner shell.

2. The quantum dot according to claim 1, wherein the size of the core is 3 nm to 15 nm.

3. The quantum dot according to claim 1, wherein the size of the quantum dot is 10 nm to 30 nm.

4. The quantum dot according to claim 1, wherein the thicknesses of the first inner shell, the second inner shell, and the outer shell are all 0.35 nm to 3.5 nm.

5. The quantum dot according to claim 1, wherein the material of the core is ZnₓCd₁₋ₓ, where x is 0.2 to 0.7.

6. The quantum dot according to claim 1, wherein the material of the core is ZnₓCd₁₋ₓ, where x is 0.4 to 0.6.

7. The quantum dot according to claim 1, wherein the material of the first inner shell layer is selected from at least one of S and ZnSeS, wherein y is x˜1, and x<y<1; the material of the second inner shell layer is selected from at least one of S, ZnCdSe, and ZnCdSeS, wherein z<y; the material of the outer shell layer is selected from at least one of ZnCdS, ZnSeS, and ZnS.

8. The quantum dot according to claim 7, wherein the material of the second inner shell layer is S, wherein z≥x.

9. The quantum dot according to claim 1, wherein the difference between the band gap of the first inner shell layer and the band gap of the core is 0.2 eV˜1 eV, the difference between the band gap of the first inner shell layer and the band gap of the second inner shell layer is 0.1 eV˜1 eV, and the difference between the band gap of the outer shell layer and the band gap of the first inner shell layer is 0.1 eV˜1 eV.

10. The quantum dot according to claim 1, wherein the number of sets of the inner shell layer unit is one;
the materials of the core, the first inner shell layer, the second inner shell layer, and the outer shell layer are sequentially Zn0.5Cd0.5S, Zn0.8Cd0.2S, Zn0.6Cd0.4S, and ZnS; or
the materials of the core, the first inner shell layer, the second inner shell layer, and the outer shell layer are sequentially Zn0.4Cd0.6S, ZnSeS, ZnCdSe, and ZnS; or
the materials of the core, the first inner shell layer, the second inner shell layer, and the outer shell layer are sequentially Zn0.2Cd0.8S, ZnSeS, ZnCdSe, and ZnS; or
the materials of the core, the first inner shell layer, the second inner shell layer, and the outer shell layer are sequentially Zn0.2Cd0.8S, Zn0.8Cd0.2S, ZnCdSe, and ZnS; or
the materials of the core, the first inner shell layer, the second inner shell layer, and the outer shell layer are sequentially Zn0.6Cd0.4S, ZnSeS, ZnCdSe, and ZnS; or
the materials of the core, the first inner shell layer, the second inner shell layer, and the outer shell layer are sequentially Zn0.7Cd0.3S, ZnSeS, ZnCdSe, and ZnS.

11. The quantum dot according to claim 1, wherein the number of sets of the inner shell layer unit is two, and each set of the inner shell layer unit includes a first inner shell layer and a second inner shell layer.

12. The quantum dot according to claim 1, wherein the materials of the core, the first inner shell layer, the second inner shell layer, the first inner shell layer, the second inner shell layer, and the outer shell layer in the direction from the core to the outer shell layer are sequentially Zn0.5Cd0.5S, Zn0.8Cd0.2S, Zn0.6Cd0.4S, Zn0.8Cd0.2S, Zn0.6Cd0.4S, and ZnS.

13. An electroluminescent device, comprising a quantum dot light-emitting layer, wherein the quantum dot light-emitting layer comprises the quantum dot according to claim 1.

14. The electroluminescent device according to claim 13 further comprising: a substrate, an anode, a hole injection layer, a hole transport layer, a quantum dot light-emitting layer, an electron transport layer, and a cathode sequentially disposed.

15. The electroluminescent device according to claim 14, wherein the material of the anode is ITO or IZO.

16. The electroluminescent device according to claim 14, wherein the material of the hole injection layer is any one of PEDOT:PSS, phosphomolybdic acid, and phosphotungstic acid.

17. The electroluminescent device according to claim 14, wherein the material of the hole transport layer is at least one of TFB, PVK, Poly-TPD, NPB, CBP, TCTA, and NiO.

18. The electroluminescent device according to claim 14, wherein the material of the electron transport layer is any one of ZnO, SnO2, and doped ZnO, wherein the dopant in the doped ZnO comprises any one or a combination of Al, Mg, Ga, Hf, N, and P.

19. The electroluminescent device according to claim 14, wherein the material of the cathode is Al or Ag.
